(19) United States
(12) Patent Application Publication
(10) Pub. No.: US 2005/0085048 A1
(43) Pub. Date: Apr. 21, 2005

(54) Method of fabricating shallow trench isolation with improved smiling effect

(76) Inventor: Yu Cheng Hsiao, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/967,155

(22) Filed: Oct. 19, 2004

(30) Foreign Application Priority Data
Oct. 21, 2003 (CN) 20031018058.X

(51) Int. Cl. H01L 21/336; H01L 21/76

(52) U.S. Cl. 438/424; 438/435

(57) ABSTRACT

A method of fabricating shallow trench isolation with improved smiling effect is provided. After an oxide layer and a silicon nitride layer are deposited on the surface of the substrate, the shallow trench is formed by an etching process. Next, a thin polysilicon layer is deposited on the surface of the shallow trench and the substrate. Oxidation is performed to form a liner oxide layer on the surface of the shallow trench and convert the polysilicon layer into a silicon oxide layer. Finally, an oxide layer is formed on the surface of the substrate to form the shallow trench isolation, thereby ensuring the coupling area between the floating gate and the gate oxide layer and the gate oxide layer and the substrate, improving the smiling effect and the leakage, thereby increasing the performance of device and the electrical quality.

### BACKGROUND OF THE INVENTION

1. Field of the Invention

The present invention relates to a method of fabricating semiconductor devices, and more particularly relates to a method of fabricating shallow trench isolation with improved smiling effect.

2. Description of the Prior Art

The conventional split-gate flash memory cell of FIG. 1, as practiced in the present manufacturing line, is found to exhibit relatively small capacitive coupling and low data retention capability. Referring to FIG. 1, a shallow trench is formed in the substrate 30. By using thermal oxidation, a liner oxide layer 32 and an oxide layer 34 are formed in the shallow trench to form the shallow trench isolation (STI) 36. The oxide layer formed on the active area of the substrate allows oxygen atoms to enter the interface between the gate oxide layer and the floating gate, causing a reduced coupling area between the floating gate and the substrate due to the so-called “smiling effect”. This is because, during any oxidation process, especially in the step of performing the oxidation of the thin polysilcon layer, the above-mentioned interface is exposed due to shallow trench isolation.

In the conventional semiconductor process, the semiconductor substrate with smiling effect due to the thermal oxidation will affect the stability of the device, resulting in hardly forming the smaller semiconductor device, reducing the yield of the device and the electrical quality. Therefore, the present invention discloses a method of fabricating shallow trench isolation with improved smiling effect.

### SUMMARY OF THE INVENTION

The present invention provides a method of fabricating shallow trench isolation with improved smiling effect. A thin polysilcon layer is formed on the surface of the shallow trench after forming the shallow trench by an etching process, ensuring the coupling area between the floating gate and the substrate, and reducing the smiling effect.

A liner oxide layer is formed on the surface of the shallow trench by using thermal oxidation, reducing the leakage of the shallow trench isolation, thereby increasing the performance of device and the electrical quality.

These objects are accomplished by providing a surface of the substrate having the oxide layer and the silicon nitride thereon; forming a shallow trench by the etching process; depositing a thin polysilicon layer; performing thermal oxidation to form a liner oxide layer and converting the thin polysilicon layer into a silicon oxide layer simultaneously; and forming an oxide layer on the surface of the substrate to form the shallow trench isolation structure in the substrate.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a drawing showing a conventional shallow trench isolation; and

FIGS. 2A to 2F are drawings illustrating the structure of each step of manufacturing the shallow trench isolation according to the preferred embodiment of the present invention.

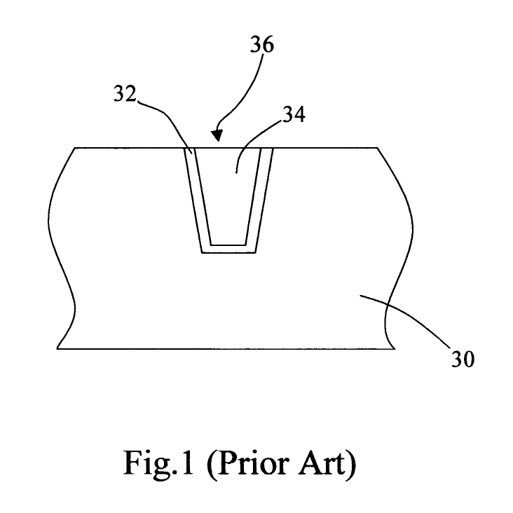

### DETAILED DESCRIPTION OF THE PREFERRED EMBODIMENTS

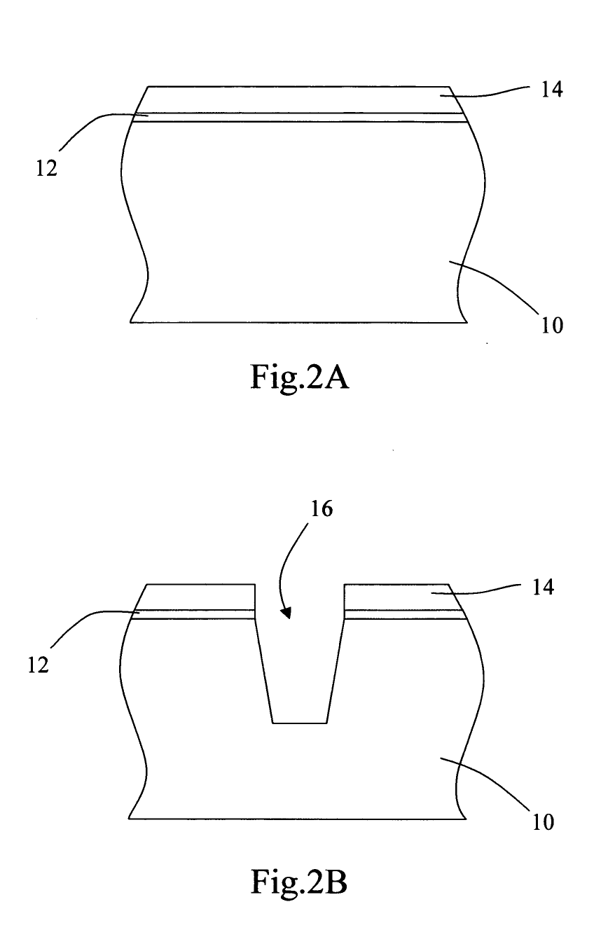

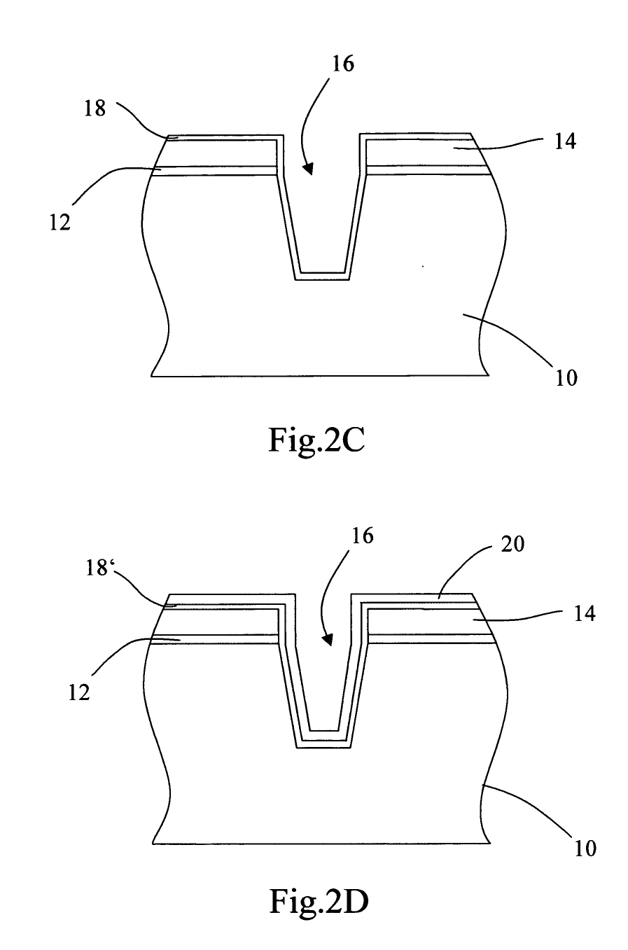

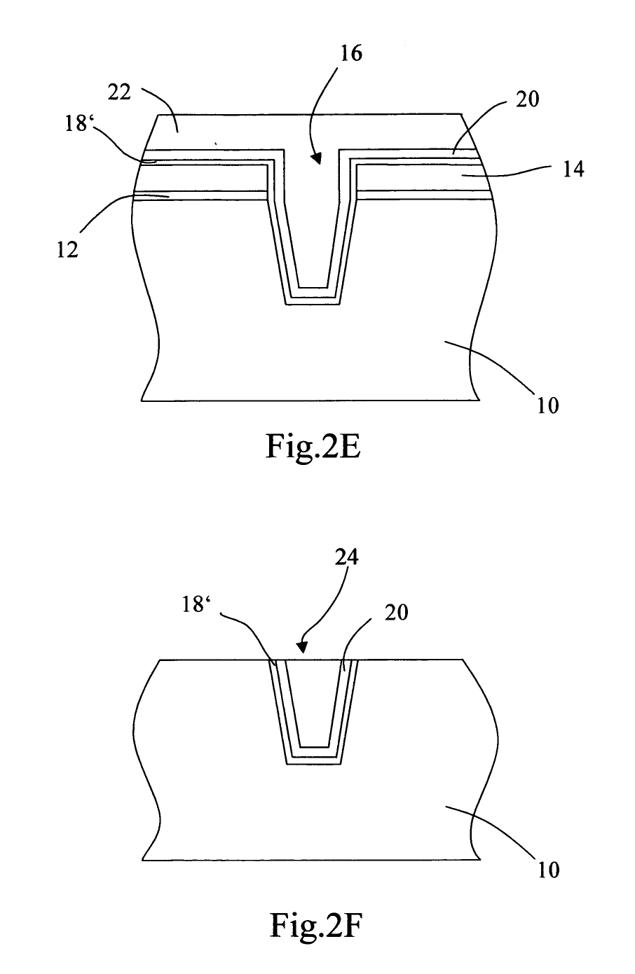

Referring to FIG. 2A, a substrate 10 is provided first. An oxide layer 12 is deposited on the substrate 10. A silicon nitride layer 14 is deposited on the surface of the oxide layer 12, wherein the material of the oxide layer 12 is SiO₂. Next, the shallow trench isolation process is performed on the substrate 10, shown in FIG. 2B. A patterned masking layer (not shown in the drawing) is formed on the substrate 10. The patterned masking layer is used as a mask. The silicon nitride layer 14, the oxide layer 12, and the substrate 10 are etched by an etching process to form a shallow trench 16 in the substrate 10, defining the active area. The shallow trench is formed by dry etching to form a dishlike structure in the substrate 10.

Refer to FIG. 2C. The masking layer is removed and a thin polysilicon layer 18 is formed on the surface of the substrate 10 and the shallow trench 16, wherein the thin polysilicon layer 18 is deposited to a thickness between about 50 angstroms by chemical vapor deposition (CVD). Next, thermal oxidation is performed to form a liner oxide layer 20 on the surface of the substrate 10 and the shallow trench 16, as shown in FIG. 2D. The liner oxide layer 20 is formed while the thin polysilicon layer 18 is oxidized to convert into the silicon oxide layer 18′ simultaneously. An oxide layer (the silicon oxide layer 18′ and the liner oxide layer 20) having a thickness of about 225 angstroms is formed on the surface of the substrate 10 and the shallow trench 16, wherein the thin polysilicon layer 18 formed in the shallow trench 16 is effectively suppressing the smiling effect. The liner oxide layer 20 reduces the leakage of the shallow trench isolation process.

Referring to FIG. 2E, an oxide layer 22 is formed on the surface of the substrate 10 to fill the surface of the shallow trench 16 and the oxide 10 by high density plasma deposition. The oxide layer 22 can be undoped silicate glass (USG). Finally, referring to FIG. 2F, the redundant oxide layer 22, the silicon nitride layer 14 and the oxide 12 on the surface of the substrate 10 are removed. The oxide layer 22, the silicon nitride layer 14, and the oxide layer 23 are removed by chemical mechanical polishing or plasma etching.

Next, semiconductor processing for fabricating the devices of the integrated circuit is performed on the substrate 10 to form a semiconductor device structure having a gate, source, and drain.

Therefore, according to the present invention, after a shallow trench is formed on the surface of the substrate, a thin polysilicon layer is deposited first to cover the surface of the shallow trench. When the oxide layer is formed by using thermal oxidation, the thin polysilicon layer is converted into the oxide layer. While the thin polysilicon can reduce the split-gate flash memory cell formation, the coupling area between the floating gate and the lower coupling oxide layer is reduced. This phenomenon is called “smiling effect”. The oxide can reduce the leakage of the shallow trench isolation, thereby increasing the performance of device and the electrical quality.

The embodiment above is only intended to illustrate the present invention; it does not, however, to limit the present invention to the specific embodiment. Accordingly, various modifications and changes may be made without departing from the spirit and scope of the present invention as described in the following claims.

1. A method of fabricating shallow trench isolation with improved smiling effect, comprising;
providing a substrate, wherein a first oxide layer and a silicon nitride layer are deposited in sequence thereon;
forming a patterned masking layer on the surface of the substrate;
etching the silicon nitride layer, the first oxide layer, and the substrate with the patterned masking layer as a mask to form a shallow trench isolation, and removing the patterned masking layer;
forming a thin polysilicon layer on the surface of the substrate and the shallow trench;
forming a liner oxide layer on the surface of the thin polysilicon layer; and
forming a second oxide layer to fill the shallow trench, and removing redundant oxide layer, the silicon nitride layer and the first oxide layer on the surface of the substrate to form a shallow trench isolation structure.

2. The method of fabricating shallow trench isolation with improved smiling effect of claim 1, wherein the etching is dry etching.

3. The method of fabricating shallow trench isolation with improved smiling effect of claim 1, wherein the thin polysilicon layer is formed by chemical vapor deposition.

4. The method of fabricating shallow trench isolation with improved smiling effect of claim 1, wherein the thickness of the thin polysilicon layer is less than 50 angstroms.

5. The method of fabricating shallow trench isolation with improved smiling effect of claim 1, wherein forming the liner oxide layer is by converting the thin polysilicon layer into the silicon oxide layer.

6. The method of fabricating shallow trench isolation with improved smiling effect of claim 1, wherein the liner oxide layer is formed by thermal oxidation.

7. The method of fabricating shallow trench isolation with improved smiling effect of claim 1, wherein the thickness of the liner oxide layer is about 225 angstroms.

8. The method of fabricating shallow trench isolation with improved smiling effect of claim 1, wherein the second oxide layer is formed by high density plasma deposition.

9. The method of fabricating shallow trench isolation with improved smiling effect of claim 1, wherein the second oxide layer is undoped silicate glass (USG).

10. The method of fabricating shallow trench isolation with improved smiling effect of claim 1, further comprises forming devices on the substrate after the shallow trench isolation structure is formed.
